(19) United States
(12) Patent Application Publication
(10) Pub. No.: US 2015/0185461 A1
(43) Pub. Date: Jul. 2, 2015

(54) Holder and Multicontact Device

(71) Applicant: Denssolutions B.V., Delft (NL)

(72) Inventor: Hendrik Willem Zandbergen, Katwijk (NL)

(21) Appl. No.: 14/657,733

(22) Filed: Mar. 13, 2015

Related U.S. Application Data
(63) Continuation of application No. PCT/NL2013/050660, filed on Sep. 13, 2013.

(30) Foreign Application Priority Data
Sep. 14, 2012 (NL) 2009469

(51) Int. Cl. G02B 21/26; H01J 37/20; G21K 5/08

(52) U.S. Cl. CPC G02B 21/26; G21K 5/08; H01J 37/20; H01J 2237/2007

(57) ABSTRACT

A holder and multicontact device for use in microscopy, a method of loading the multicontact device, a container for the multicontact device, and a microscope comprising said holder and device. The invention is in the field of microscopy, specifically in the field of electron and focused ion beam microscopy. However, its application is extendable in principle to any field of microscopy.

### CROSS-REFERENCE TO RELATED APPLICATIONS

This application is a continuation of Patent Cooperation Treaty Application No. PCT/NL2013/050660, entitled “Double Tilt Holder and Multicontact Device”, filed Sep. 14, 2014, which claims priority to and the benefit of Netherlands Patent Application Serial No. 2009469, entitled “Double Tilt Holder and Multicontact Device”, filed Sep. 14, 2012, and the specification and claims thereof are incorporated herein by reference.

### STATEMENT REGARDING FEDERALLY SPONSORED RESEARCH OR DEVELOPMENT

Not Applicable.

### INCORPORATION BY REFERENCE OF MATERIAL SUBMITTED ON A COMPACT DISC

Not Applicable.

### COPYRIGHTED MATERIAL

Not Applicable.

### BACKGROUND OF THE INVENTION

1. Field of the Invention (Technical Field)

The present invention is in the field of a holder and multicontact device for use in microscopy, a method of loading the multicontact device, a container for the multicontact device, and a microscope comprising said holder and device.

2. Description of Related Art

The present invention is in the field of microscopy, specifically in the field of electron and focused ion beam microscopy. However it application is extendable in principle to any field of microscopy.

Microscopy is a technique used particularly in semiconductor and materials science fields for site-specific analysis, and optionally deposition, and ablation of materials. In microscopy typically a source is used to obtain an image. The source may be a source of light, electrons, and ions. Further scanning techniques have been developed using e.g. atomic force (AFM) and scanning tunneling. A modern microscope can image a sample with an optimal spot size typically in the order of a few nanometers for FIB and EM and a few hundred nanometers for an optical microscope.

A drawback of various types of microscopes is that a sample can not be viewed or imaged optimally, e.g. in that not all or some details considered relevant are visible.

Another drawback is that typically samples run a serious risk of getting damaged, specifically when entered into a microscope, but also when inspected or manipulated.

Further manipulating samples spatially is typically limited or impossible and is typically cumbersome.

If a sample needs to be manipulated in order to establish characteristics thereof and/or to change characteristics thereof such typically involves dedicated solution, which solutions can not be used in other situations, due to, e.g., limitations thereof. Even further such manipulation is typically performed in a non-standardized manner.

The manipulations are typically not error proof and prone to mistreatment. Samples may further get damaged, may malfunction, may get detached, etc.

Results of inspections are e.g. as a consequence of the above unreliable, not detailed enough, not precise enough, etc.

Incidentally US2008067374 (A1) recites a specimen holder for a TEM including a specimen holder electrode connectable to a mesh electrode and current inlet terminals as well are provided. Voltage is applied externally of the specimen analyzing apparatus to the external voltage applying portions of the specimen through the medium of the specimen holder electrode and mesh electrode. The specimen holder has similar drawbacks as the prior art.

The present invention therefore relates to a holder and multicontact device for use in microscopy, a method of loading the multicontact device, a container for the multicontact device, and a microscope comprising said holder and device, which solve one or more of the above problems and drawbacks of the prior art, providing reliable results, without jeopardizing functionality and advantages.

### BRIEF SUMMARY OF THE INVENTION

The present invention relates in a holder according to claim 1, a multicontact device according to claim 6, a combination of the holder and device according to claim 9, a microscope according to claim 10, a method of loading a multicontact device into a holder according to claim 13, and a container for receiving a sample according to claim 14.

Thereby the present invention provides a solution to one or more of the above mentioned problems and drawbacks.

Advantages of the present description are detailed throughout the description.

### DETAILED DESCRIPTION OF THE INVENTION

The present invention relates in a first aspect to a double tilt holder according to claim 1.

The holder is specifically designed to be incorporated into a microscope, such as an electron microscope, and to be manipulated therein. In order to manipulate a sample the holder is provided with a rotation axis β, which is a virtual axis. As such a second rotational axis is provided. In an example the axis β may also be a real axis for rotation, such as a metal axis, or may form part thereof. In the description an axis may refer to a virtual axis and/or a real axis, and in case of a real axis may for part thereof. In the latter case the axis β may be provided in one or more of the holder, the multicontact device and receiving unit. Therewith the multicontact device in the receiving unit can be rotated freely around said axis β, or at least to a large extent. The present holder allows rotation of + or −60° around axis β with a precision of ±0.25° in a well-controlled and reproducible manner. In principle a higher degree of rotation is possible, however it becomes more difficult to maintain sufficient contact and a risk of damaging especially contacts increases at relatively higher angles. Amongst others an improved reliability is obtained, e.g. of electrical contacts when exchanging samples.

In order to rotate around axis β a rotator is provided. The rotator can be an electric rotor, a mechanical rotor, such as a spring rotor, a fluid pressure induced rotor, a magnetic rotor, and combinations thereof. Typically the rotator is provided with means for precisely rotating, such as a step motor, and means for controlling said precise rotation.

In order to maintain the multicontact device in position, optionally to fix the device, and to position the device precisely a receiving unit is provided. The receiving unit maintains the device during use of the microscope, only allowing some drift, e.g. due to temperature change, of less than a few nanometer per minute. Such drift can be corrected for. The receiving unit may be a part of the holder or be a separate unit positioned in the holder.

Even further, by providing a second rotation axis α, as is detailed below, a sample or multicontact device can be positioned in such a way that it can be viewed under a broad range of inspection angles. It is preferred to rotate the receiving unit, the unit comprising the sample or device. Therewith details of the sample, such as edges, grain boundaries, crystal structure, surface details, composition, can be inspected.

In order to manipulate a sample conducting pins are provided, which pins can be in electrical connection to one or more contacts of the sample and with electronic devices, such as control means etc. Therewith for instance stimuli to a sample can be provided. In order to manipulate a sample the conducting pins can make connection with the contacts or can break the connection. Thereto the pins can move in a direction perpendicular to the axis β. Typically the pins remain in good connection with the multicontact device, in particular when rotating the holder around axis β, thereby providing a reliable and controlled connection.

In an example of the present holder the receiving unit is adapted to receive the multicontact device, such that the multicontacts are located essentially on a center of the axis β. As such the holder and multicontact device may be regarded as one, specifically in view of manipulation thereof. By providing the contacts essentially on the center of the axis β a good contact between pins and contacts is remained, even when rotating the holder. As such a reliable contact is provided, even when rotating over relatively large angles, such as + or −60°. By aligning contacts parallel to the axis β advantages are obtained for all contacts.

In an example of the present holder the electrically conducting pins are aligned substantially parallel to a length axis λ of the holder, the axis λ being perpendicular to the first axis β. By aligning the pins, typically being needle like, along the axis λ a high degree of freedom for positioning is obtained, as well as a reliable way of securing electrical contact. If spring-like pins are used it is preferred to have pins of sufficient length, and as a consequence also a holder of sufficient length. Therefore a length of the pins in from 1-5 cm, such as 3 cm.

In an example the pins provide a spring-like contact, such as by a metal pin. The pins may be of a metal, such as copper, stainless steel, aluminum, tungsten, or alloys thereof.

In an example of the present holder the holder comprises 4 or more electrical pins, such as 8 or more pins. The present design specifically relates to a multitude of contacts. Examples are provided with 4 or 8 contacts. However, the design allows for a multitude thereof, if required, the number being limited from a practical point of view by space available along the axis β, size of contact and space in between contacts. It is further considered to combine various functions of the contacts, such as providing an electrical current in combination with providing an analog or digital signal. Therewith a high degree of freedom is provided for manipulating, inspecting and analysing the sample with electro-magnetic means.

In an example of the present holder the holder comprises one or more of
a first entrance for receiving the multicontact device, the first entrance preferably located at a side of the holder parallel to the second axis
a first sled for guiding the multicontact device from the first entrance towards the receiving unit,
one or more electrical pins being moveable parallel to the axis β,
one or more electrical pins being fixed parallel to the axis β,
an aligning means for receiving and aligning the multicontact device, and
a second axis α for rotating the holder.

The first entrance may be located at a side of the holder, at a top thereof, or at a bottom thereof. Such is not regarded critical. A practical point of view seems important, such as ease of use. Also the sample is preferably not contacted (directly), in order to maintain the sample in an original and pristine state. Further a sample may be provided on a support, such as a membrane, which membrane is very prone to being damaged when being manipulated, in particular when contacted. In an example the entrance is located at a side of the holder.

In order to move the multicontact device from the entrance to the receiving unit a sled may be provided. The sled can be a groove, a ridge, or the like, and combinations thereof. In order to support and/or improve guidance the multicontact device may comprise a groove, a ridge etc. likewise.

In an example one or more electrical pins may be moveable parallel to the axis β, thereby allowing to make contact to a selection of contacts on the multicontact device. As a consequence the pins may be connected to a specific contact envisaged, providing, e.g., a specific function, such as provision of an electrical current. During operation a pin may be connected to a further contact, e.g. in order to provide a further function. As a consequence the number of pins may be smaller than the number of contacts, still providing a high degree of functional flexibility. Likewise one or more electrical pins being fixed parallel to the axis β. Such provides a minimized risk of malfunction, e.g. in terms of breakage of a pin, not complete or absent contact, etc. The pins itself may be connected to a controller or the like, the controller being capable of, e.g., (functional) switching, (functional) connecting, etc. As a consequence a high degree of flexibility in functionality may be provided to a contact of the multicontact device. In a preferred example most or all of the functional flexibility may be provided in a control box or the like.

In an example an aligning means for receiving and aligning the multicontact device is present. The aligning means may for instance relate to a means for (assisting of) pushing the multicontact device through the entrance to an intended position in the holder. Such a position may be an initial position, from which the multicontact device is moved towards its final position, such as in the receiving unit, or may be a final position, e.g., in the receiving unit.

In an example a second axis α for rotating the holder is present. As a consequence a sample may be rotated in virtually any orientation, especially as the second axis α may be perpendicular to the first axis β, especially as also a further rotating means is provided for rotating the holder around the axis α. The further rotating means may be incorporated in the holder itself, or may rotate the holder or part thereof externally.

As a high degree of integration of various components and functions is provided by the present invention also e.g. a high degree of reliability is provided.

In an example of the present holder the holder comprises fixing means for the multicontact device and fixing means for the pins. As such an intended position is provided and maintained, as long as required. The fixing means may be clamps, screws, etc.

In a second aspect the present invention relates to a multicontact device according to claim 7. In order to manipulate the device two or more contacts are provided. The contacts are provided along an axis γ thereof, which axis may also function as a rotating axis.

It is noted that the term “substantial” is intended to indicate that within a given accuracy, such as measurement, manufacturing, etc. elements are, e.g., in line, etc.

In order to maintain the device in an original state, when loading, when inspecting, when removing, etc. strengthening means, such as a container, are provided, wherein the device is inserted. The strengthening means are of a relatively stiff material and of a material which can be fabricated easily, such as a metal or plastic, e.g., stainless steel. The container may also be made of any other suitable material. A suitable container is the present container.

In an example of the present multicontact device it comprises 4 or more contacts, such as 8 or more contacts, and/or wherein the contacts are lowered with respect to a top surface thereof. The number of contacts may be more or less, depending on requirements, such as of inspection. In order to position the contacts as precisely as possible on a center of the axis γ thereof the contacts are lowered with respect to a surface of the device. Preferably the contacts are lowered as far as required and also internal connections are lowered equivalently. The axis γ thereof is used for rotating the device. By lowering the contacts a good connection is maintained during an optional rotation.

In a third aspect the present invention relates to a combination of the holder according to the invention and the multicontact device according to the invention, wherein the axes γ and β are one and the same. In principle the present holder may be combined with a multicontact device not according to the invention, which is suitable for use in the present holder. Likewise, the present multicontact device may be combined with a holder not according to the invention, which is suitable for use as a holder, e.g. in a microscope. The holder and device are preferably designed such that the axes γ and β are one and the same when the combination is formed, i.e. the holder and device are assembled and ready for inspection or being inspected. Both axes may be (partly) virtual and (partly) real, in that a rotation of the sample or device around said axes is provided.

In a fourth aspect the present invention relates to a microscope selected from an electron microscope, an ion microscope, an atomic force microscope, and an optical microscope, such as a TEM, a SEM, a transmission mode SEM, an STM, an FIB microscope, preferably using He ions, comprising a holder according to the invention. Further the present multicontact device or a similar device may be included in the holder. The present invention has a broad range of applications, without a need for further adaptation. Even further the present holder is designed to cooperate with a microscope, e.g. in terms of functionality, ease of use, mutual commensurability, etc.

In an example of the present microscope it further comprises one or more of a control means selected from a controller, an ampere meter, a voltage meter, a heating means, a radiation source, a means for receiving the holder, an image forming device, and a second rotator for rotating along an axis α, such as a goniometer. With the ampere meter a current can be measured, which current is indicative for various characteristics of a sample. Likewise a voltage may be measured. The heating means may be provided to heat a sample or part thereof. The radiation source may provide photons, electrons, ions, etc., depending on the type of microscope used. The image forming device may be a lens or lens system, a camera, a monitor, and combinations thereof. The microscope comprises a means for receiving the holder, preferably the present holder, and an optional means for rotating the holder or controller thereto.

In a fifth aspect the present invention relates to a method of loading a multicontact device in a holder for use in a microscope, comprising the steps of
providing the multicontact device, and the holder,
loading the multicontact device through an entrance of the holder,
moving the multicontact device to a receiving unit of the holder, and
fixing the multicontact device in the receiving unit.

The multicontact device is in an example loaded into the present container, before loading into the holder.

In an example the multicontact device is loaded from a side of the holder into the holder.

In an example the loading of the multicontact may take place from a bottom side of the holder, opposite to the connecting pins thereof. The multicontact device may already be enclosed in the present container. As such loading is further simplified, e.g. in terms of steps to be taken. Further, connecting pins may remain in place. Such provides a more reliable contact between pins and contacts of the device. Even further, connecting pins need not be manipulated any more, thereby means of fixing and means of manipulating the pins become redundant, leading to s further simplified holder.

In a sixth aspect the present invention relates to a container for receiving a sample, such as a multicontact device, such as a chip, to be placed in a microscope, comprising a platform for receiving the sample, at least three edges for maintaining the sample in position, a grip for manipulating the container, a rotation axis β for rotating the container, and optionally a closing means. The container may be made from metal, such as stainless steel, copper, aluminum, or alloy, of a ceramic material, of a metal oxide, or in general of an electrical conducting material. The container comprises a platform for receiving a sample, such as a multicontact device. The platform and sample are designed to be of equal size (length and width). In order to maintain the sample in position at least three edges are provided, the edges being of sufficient height. The grip is meant for manipulating the container be a user. Preferably the container can be closed, thereby fixing the sample in a third dimension and supporting maintenance of the sample in its original and pristine state.

In an example the present container comprises an opening allowing image formation at a bottom side thereof. If, e.g., the container is closed at a top side thereof an opening may be provided at the bottom. The opening is typically of such a dimension that only the sample or part thereof which is intended to be inspected is visible.

The one or more of the above examples and embodiments may be combined, falling within the scope of the invention.

The invention is further detailed by the accompanying figures, which are exemplary and explanatory of nature and are not limiting the scope of the invention. To the person skilled in the art it may be clear that many variants, being obvious or not, may be conceivable falling within the scope of protection, defined by the present claims.

### SUMMARY OF THE FIGURES

The invention although described in detailed explanatory context may be best understood in conjunction with the accompanying figures.

FIGS. 1a and 1b show a holder according to the invention.

FIG. 2 shows a multicontact device according to the invention.

FIG. 3 shows a holder comprising a multicontact device according to the invention.

FIGS. 4a, 4b and 4c show a receiving unit according to the invention. In FIG. 4a the receiving unit is open, in FIG. 4c the receiving unit is closed. In FIG. 4b also a multicontact device is visible.

### DETAILED DESCRIPTION OF THE FIGURES

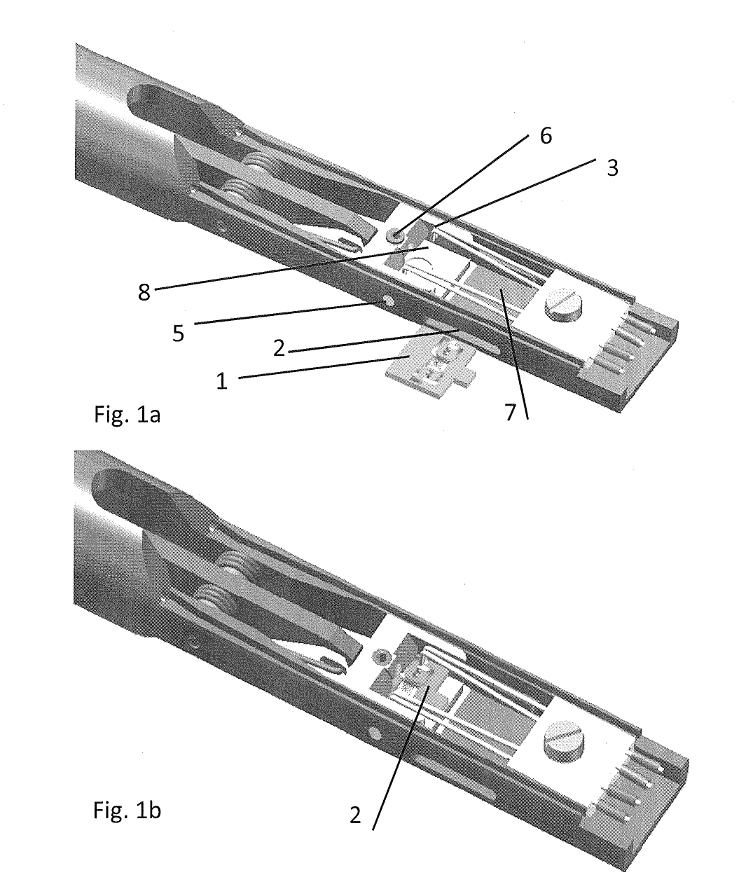

In FIG. 1a a top part of the holder is shown. Further a multicontact device (1) is shown, to be entered into the holder through an entrance (2) thereof. Also a support (7) and a sled or groove (not shown) may be provided. After being inserted into the holder the multicontact device is positioned in the receiving unit (8). Conducting pins (3) are shown, in this case 4 pins. The pins can be lifted and lowered. By allowing some amount of spatial freedom the pins can also move to some extend parallel to the axis β. For rotating the receiving unit (8) an axis β (5) is provided, as well as a rotator, in this case a handle shown in the middle. The multicontact device may be fixed by a screw (6) or the like.

In FIG. 1b the multicontact device (2) is shown after being secured in the receiving device. The connecting pins are in electrical contact with the contacts of the multicontact device. Screws have been fixed in order to secure the position of the multicontact device and also of the connecting pins.

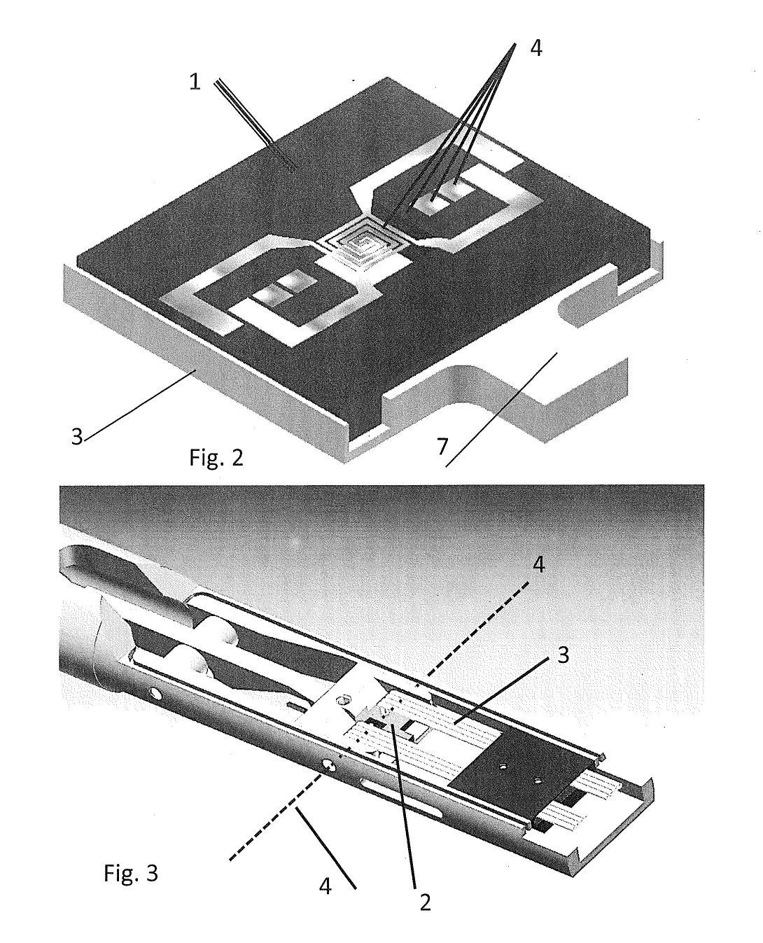

In FIG. 2 a view of a multicontact device is presented. The multicontact device (1) is supported by strengthening means, in this case a container (3). The container comprises a grip (7) for manipulating the multicontact device and container, such as when entering the two in the present holder or removing it therefrom. Further 4 contacts (4) at a right side are indicated, whereas 4 more are visible. On the multicontact device tracks are visible, e.g. for providing an electrical current, such as for heating a sample. The container has edges for maintaining the multicontact device in position.

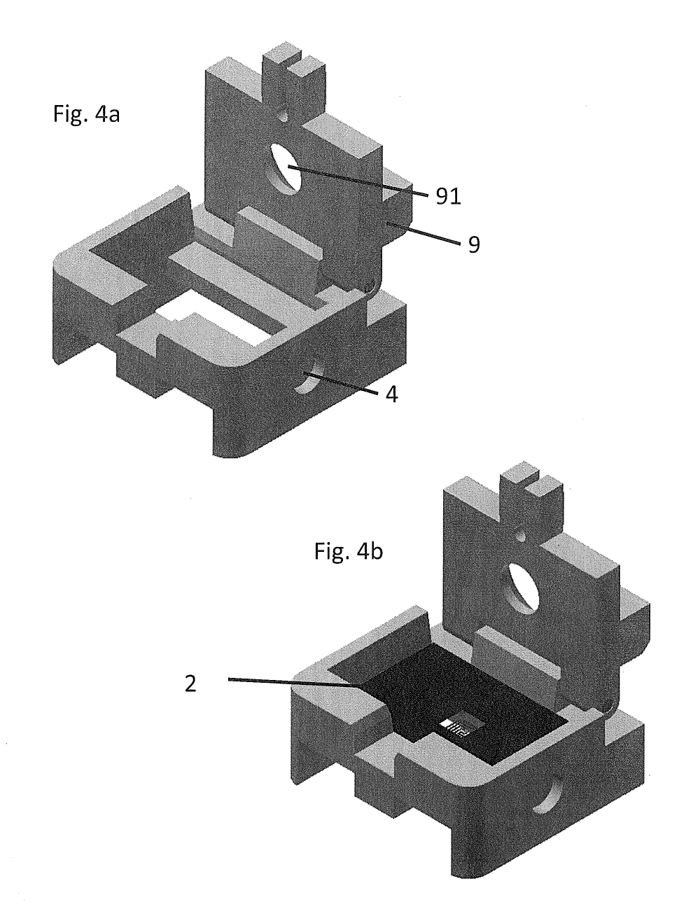

In FIG. 3 the holder comprising a multicontact device (2) with in the example having 8 contacts, is in operational mode. 8 connecting pins (3) are in a lowered position in full contact with the contacts of the multicontact device. The pins and contacts are located on the axis β (4). In an example the pins and contacts are located on the center of the axis β.

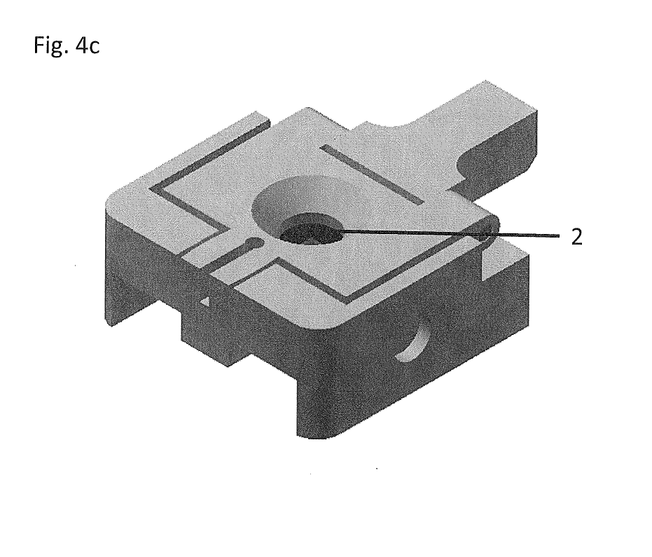

In FIG. 4a a receiving unit is shown. Therein the virtual axis β (4) is shown as an opening. The receiving unit is made of a suitable material. It comprises a cover part (9) which can be a separate part, but preferably is integrated in the receiving unit. The cover part (9) rotates along an axis thereof. The cover part also contains an opening (91) allowing inspection of a sample to be introduced.

In FIG. 4b the multicontact device (2) is introduced into the receiving unit. The device is situated on a membrane.

In FIG. 4c the receiving unit is closed. The multicontact device (2) is visible partly. The present receiving unit has some degree of flexibility. As such a flexural characteristics thereof supports in fixing a multicontact device adequately, and at the same time minimizing a risk of damage.

What is claimed is:

1. A holder for cooperating with a multicontact device for use in a microscope,
wherein the holder has a receiving unit for receiving and maintaining the multicontact device,
wherein the holder has an axis β for rotating the receiving unit, and a rotator for rotating the unit along said axis β, and
wherein the holder comprises two or more electrically conducting pins, each electrical pin being electrically connected to a control means, each electrical pin being moveable perpendicular to the axis β for providing or breaking electrical connection with a contact of the multicontact device.

2. The holder according to claim 1, wherein the receiving unit is adapted to receive the multicontact device, such that the multicontacts are located essentially on a center of the axis β.

3. The holder according to claim 1, wherein the electrically conducting pins are aligned substantially parallel to a length axis λ of the holder, the axis λ being perpendicular to the first axis β, and/or wherein the pins provide a spring-like contact.

4. The holder according to claim 1, wherein the holder comprises 4 or more electrical pins.

5. The holder according to claim 1, wherein the holder comprises one or more of
a first entrance for receiving the multicontact device, the first entrance preferably located at a side of the holder parallel to the second axis β,
a first sled for guiding the multicontact device from the first entrance towards the receiving unit,
one or more electrical pins being moveable parallel to the axis β,
one or more electrical pins being fixed parallel to the axis β,
an aligning means for receiving and aligning the multicontact device, and
a second axis α for rotating the holder.

6. The holder according to claim 1, wherein the holder comprises fixing means for the multicontact device and fixing means for the pins.

7. A multicontact device for use in a microscope, comprising two or more contacts, the contacts being substantially located parallel to an axis β thereof, and wherein the device comprises strengthening means.

8. The multicontact device according to claim 7, comprising 4 or more contacts and/or wherein the contacts are lowered with respect to a top surface thereof.

9. A combination of the holder according to claim 1 and a multicontact device for use in a microscope, comprising two or more contacts, the contacts being substantially located parallel to an axis thereof, and wherein the device comprises strengthening means.

10. A microscope selected from an electron microscope, an ion microscope, an atomic force microscope, and an optical microscope, such as a TEM, a SEM, a transmission mode SEM, an STM, an FIB microscope, preferably using He ions, comprising a holder according to claim 1.

11. The microscope according to claim 10, further comprising one or more of
a control means selected from a controller, an ampere meter, a voltage meter, a heating means,
a radiation source,
a means for receiving the holder,
an image forming device, and
a second rotator for rotating along an axis α.

12. A method of loading a multicontact device in a holder according to claim 1 for use in a microscope, the method comprising the steps of
providing the multicontact device and the holder,
loading the multicontact device through an entrance of the holder,
moving the multicontact device to a receiving unit of the holder, and
fixing the multicontact device in the receiving unit.

13. The multicontact device according to claim 7 to be placed in a microscope, additionally comprising a platform for receiving the sample, at least three edges for maintaining the sample in position, a grip for manipulating the container, and a rotation axis β for rotating the container.

14. The device according to claim 13, additionally comprising an opening allowing image formation at a bottom side thereof.
